(19) United States
(12) Patent Application Publication
(10) Pub. No.: US 2023/0217167 A1
(43) Pub. Date: Jul. 6, 2023

(54) VEHICLE AUDIO ENHANCEMENT SYSTEM

(71) Applicant: FORD GLOBAL TECHNOLOGIES, LLC, DEARBORN, MI (US)

(72) Inventors: Stuart C. Salter, White Lake, MI (US); Hussein Berry, Dearborn, MI (US); Annette L. Huebner, Highland, MI (US); Lucretia L. Williams, Bloomfield Hills, MI (US); Robert W. McCoy, Ann Arbor, MI (US); Monica Lam, Northville, MI (US); John R. Van Wiemeersch, Novi, MI (US)

(21) Appl. No.: 17/569,006

(22) Filed: Jan. 5, 2022

(51) Int. Cl. H04R 3/12; H04R 1/10; H04R 3/04; H04R 1/40; H04R 3/00; H04R 1/02; H03G 3/30

(52) U.S. Cl. CPC H04R 3/12; H03G 3/3005; H04R 1/025; H04R 1/403; H04R 1/406; H04R 1/1041; H04R 3/04; H04R 3/005; H03G 2201/103; H04R 2201/401; H04R 2420/07; H04R 2499/13

(57) ABSTRACT

The invention is an apparatus used to send sound exterior to the vehicle to a location on the interior of a vehicle which corresponds with the sound’s external location. The apparatus adjusts for gain by frequency and shifts frequencies of the audio signals received exterior to the vehicle to generate a modified audio signal. The adjustments include compensation for hearing loss, compensation for audio in the interior of the vehicle, and attenuation adjustments for unwanted exterior noise. The modified audio signal is generated by filtering unwanted audio from the exterior audio, adjusting for gain by frequency and shifting/compressing frequencies according to hearing deficiencies, and adjusting for gain by frequency according to audio in the interior of the vehicle. The modified audio signal may be limited to a maximum gain and then amplified in the interior of the vehicle.

### CROSS REFERENCE TO RELATED APPLICATIONS

Not Applicable.

### STATEMENT REGARDING FEDERALLY SPONSORED RESEARCH

Not Applicable.

### BACKGROUND OF THE INVENTION

An important goal of automobile manufacturers is to build a vehicle which shields the interior from exterior noise. The perceived quality of a vehicle can depend on the level of sound insulation. However, times do exist when a vehicle occupant (e.g., driver) wants to hear what is happening on the outside of the vehicle. For instance, the driver may want to communicate with a person directly or use an outside intercom at a restaurant drive-through, hear outside nature or background sounds. While diagnosing vehicle performance during a test drive, a mechanic may be assisted by hearing some aspect of the sounds produced by the vehicle from the exterior while it is in motion. Merely opening a window may not be adequate for various reasons including relative positions, weather, quietness of the exterior sound, or hearing loss which the occupant may possess. A multitude of these reasons may easily be present at the same time.

Use of simple sound reproduction (e.g., an intercom) between the interior and exterior of a vehicle may not achieve satisfactory results. Depending upon the state of the vehicle and the nature of the surroundings, undesirable noises (e.g., wind) may overwhelm the desired sounds. Furthermore, some occupants of a vehicle may have hearing loss that impacts their ability to perceive sounds being reproduced.

### SUMMARY OF THE INVENTION

The present invention relates in general to hearing assistance and, more specifically, to hearing assistance which can be provided by a vehicle audio system. The audio system may increase a reproduced sound level at frequencies which the listener is deficient in hearing. The interior of a vehicle is designed to keep exterior sound out of the cabin, but there are many circumstances where the occupant would like to hear the exterior sounds. This invention eliminates several factors which prevent an occupant from hearing exterior sound.

In one aspect of the invention, an apparatus that transfers sounds from the exterior to the interior of a vehicle. It uses an array of exterior transducers and an array of interior transducers to reproduce sounds from the exterior to the interior of the vehicle. The apparatus may comprise a control circuit which adjusts the sound level (e.g., gain) by frequency of the audio signals received exterior to the vehicle to generate a modified audio signal. The adjustments for gain by frequency may include compensation for hearing loss, compensation for competing sounds in the interior of the vehicle, and attenuation adjustments (i.e., filtering) for unwanted exterior noise. The unwanted exterior noise (e.g., wind noise) can be estimated by vehicle speed and exterior transducer location. An amplifier transfers the modified audio signal from the control circuit to the array of interior transducers.

In another aspect of the invention, an apparatus receives audio on the exterior of the vehicle and generates a modified audio signal by filtering unwanted audio from the exterior audio, adjusting for gain by frequency according to hearing deficiencies, and adjusting for gain by frequency according to background audio in the interior of the vehicle. The apparatus reproduces the sound in the interior of the vehicle by amplifying the audio according to the combination of filters and gains according to frequency of the sound. A limiter may be used to restrict the modified audio signal to a maximum gain. Using multiple audio channels for both the exterior and interior sounds, audio is reproduced in the vehicle interior with a sound field that corresponds with the external audio’s original direction.

### BRIEF DESCRIPTION OF THE DRAWINGS

FIG. 1 is a top view of a vehicle’s interior and exterior which includes interior and exterior transducers as well as an occupant’s wireless transducers and direction of gaze.

FIGS. 2A and 2B are graphs depicting exterior noise and a corresponding adjustment to suppress the noise in an audio signal, respectively.

FIGS. 3A and 3B are graphs depicting an occupant’s hearing loss and a gain adjustment to compensate for the occupant’s hearing loss, respectively.

FIGS. 4A and 4B are graphs depicting the sound created by a HVAC (Heating, Ventilation, and Air Conditioning) blower and the adjustment for gain based on each of three blower settings.

FIG. 5 is a functional block diagram of a control circuit.

FIG. 6 is a block diagram showing inputs and outputs of a control circuit.

FIG. 7 is a flowchart showing one exemplary embodiment of a method to reproduce audio exterior to a vehicle into an interior of a vehicle.

### DETAILED DESCRIPTION OF PREFERRED EMBODIMENTS

Embodiments of the invention involve a vehicle being used as a specialized hearing aid by using an apparatus to transfer exterior sound to the interior of the vehicle. To assist in hearing, the original exterior audio signal is changed to a modified audio signal using gain and attenuation profiles and in some instances shifting sounds from one frequency range to another. This beneficial modification is completed by adapting the signal to account for factors which reduce the ability of an occupant to adequately hear exterior audio. Factors which can inhibit accurate hearing of exterior sound are individual hearing deficiencies, exterior noise sources, and sources of other interior noises. An array of transducers (e.g., microphones) is used outside of the vehicle to capture the originating exterior audio signal, and an array of transducers (e.g., loudspeakers) is used inside of the vehicle to reproduce a multi-channel modified audio signal in a way that recreates the apparent locations from which the external sounds are coming (i.e., duplicating the external sound field). A multi-channel audio amplifier drives the internal transducers using the modified audio signal.

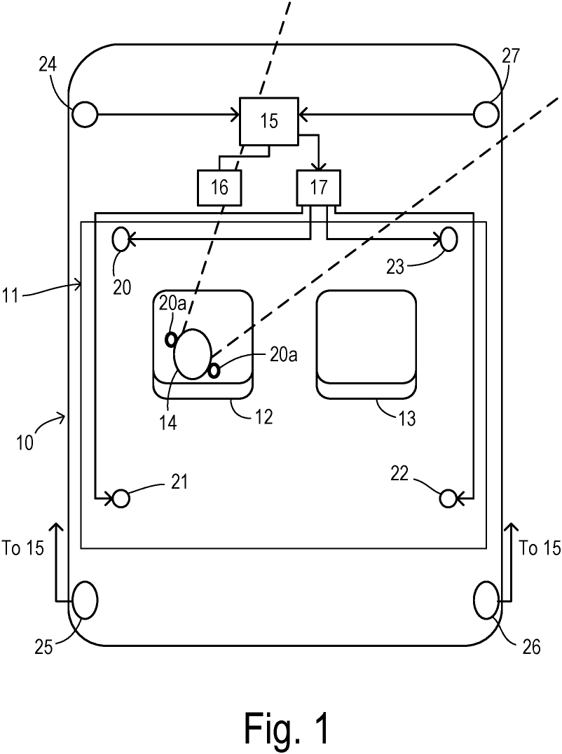

FIG. 1 shows a vehicle 10 which has an interior cabin 11. Inside the cabin of the vehicle are a driver seat 12 and a passenger seat 13. The driver seat is occupied by an occupant 14. A control circuit 15 is coupled to a human machine interface (HMI) 16 and an amplifier 17. The control circuit receives signals from an array of external transducers 24-27. Transducers 24-27 may be comprised of microphones and/or other sound pickup devices (e.g., window glass-based microphones or body sheet metal microphones using an exciter attached to the flat surfaces). Amplifier 17 transfers adjusted audio signals to an array of interior transducers 20-23. The arrays can be comprised of other numbers of transducers, and there is no need for the internal array and external array to have the same number of transducers. The array of external transducers 24-27 collects a multi-channel surround-sound audio field with the number of channels determined by the number of microphone transducers. The array of internal transducers 20-23 reproduces a multi-channel surround-sound audio field with the number of channels determined by the number of loudspeaker transducers. Known signal mixing and steering methods can be employed to approximate the external sound field when outputting the multi-channel modified audio signal.

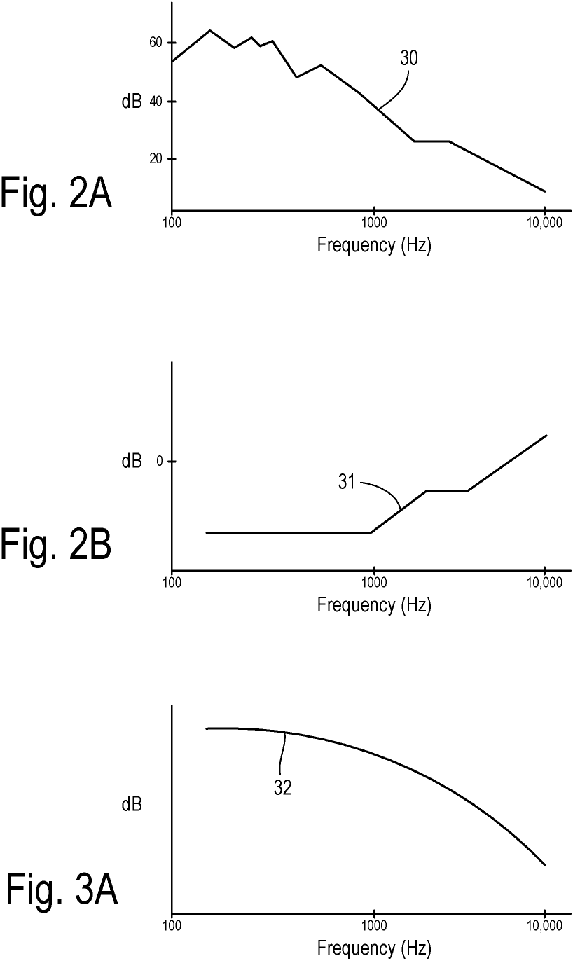

The array of external microphones 24-27 on the exterior of a moving vehicle is subject to significant wind noise. This noise is dependent on the speed of the vehicle and the location of the microphones on the vehicle. It is advantageous to mitigate the effects of wind noise on the microphone signals before any further processing of audio. FIG. 2A shows a graph of the wind noise that can be picked up by an exterior transducer (or other noise including engine noise or noise of tires on any surface). A trace 30 shows exterior vehicle noise in decibels (dB) varying by frequency which is being picked up by a front right transducer when the vehicle is traveling at one particular speed while in a particular gear on a particular type of road surface. As seen in the graph, a frequency range containing the majority of the sound is from about 100 Hz to about 1000 Hz. The invention may utilize a database (e.g., lookup table) covering a range of conditions (e.g., speed, gear, road surface) for estimating noise present at any particular microphone during any driving situation. It is desirable to mitigate this wind noise by filtering it out where possible. FIG. 2B shows a graph with a trace 31 showing an attenuation adjustment of microphone signals varying by frequency. Because the majority of unwanted sound is between the 100 Hz to 1000 Hz range, the attenuation adjustment includes a heavier filtering out of the sound in this range. Other known techniques may also be used to cancel wind noises from the microphone signals.

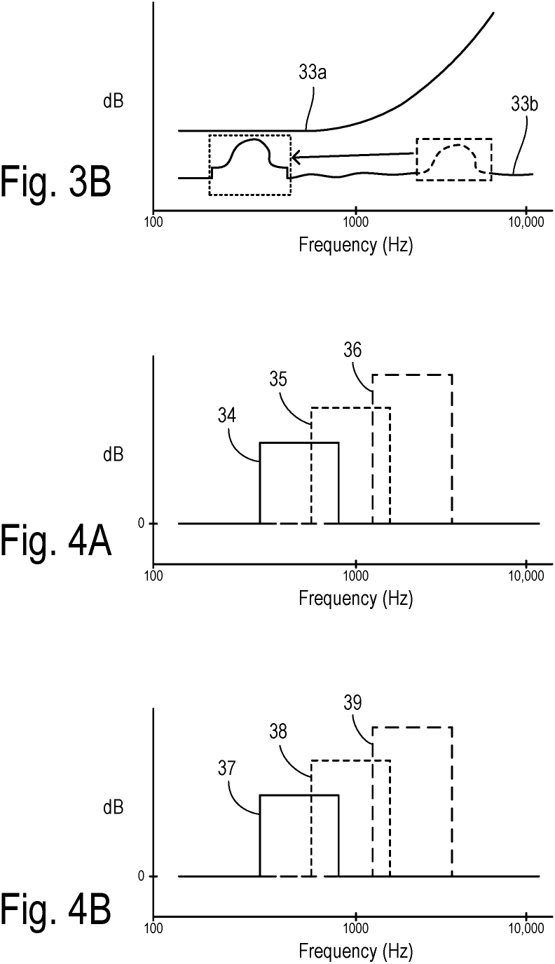

After the audio signals from the microphone array are scrubbed of exterior wind noise, there are still other factors limiting the ability of the occupant to hear exterior sounds, one of which is hearing loss. FIG. 3A shows an audiogram 32 as an example of a hearing capability of a vehicle occupant. Trace 32 represents a threshold of hearing which varies by frequency. The hearing deficiencies shown are unique to a respective occupant. In some embodiments, data for particular occupants can be saved in a memory for use with the corresponding occupant. When this occupant is in the vehicle, the apparatus makes an adjustment for gain by frequency and/or for shifting of frequency of an audio signal, in a manner which best compensates for the hearing deficiencies of the occupant. An adjustment comprising a gain boost by frequency is shown by trace 33a in FIG. 3B. Likewise, an adjustment may be comprised of shifting sounds which are present at a frequency range where a user’s hearing is compromised to a different (e.g., lower) frequency range where the user’s hearing is better, as shown by shifting a portion of an audio signal 33b in FIG. 3B from a higher frequency range to a lower frequency range. In some embodiments, the frequency shift may be comprised of compressing an entire audible frequency spectrum. For example, an audio signal can be lowpass filtered (e.g., removing frequencies above 6 KHz since human speech falls mainly below 6 KHz) and shifting down all remaining frequencies at a ratio of about ½. Although the tones of the sound are distorted, they can be adapted to a region of better hearing sensitivity of the occupant.

The modified audio signals are reproduced by internal speakers to be heard by the vehicle occupant. The main loudspeakers for the passenger cabin can be used. In order to direct the reproduced audio to an intended occupant when more than one occupant is present in the passenger cabin, speakers mounted in the headrests for the respective seating positions can be used. Since the headrest speakers are close to the head of the intended occupant, the modified sounds can be directed to the person having the associated hearing loss compensation without those sounds being overwhelming to other occupants. In another embodiment, modified audio signals can be directed to only the main speakers closest to the intended occupant, although directional cues in the resulting sounds would be lost.

Competing sounds in the interior of the vehicle can mask the desirable sounds that are being reproduced from the exterior. A frequency selective boost of the desired exterior sounds at the corresponding frequencies where the competing sounds are present can help overcome any masking of the desired sounds from the exterior. FIG. 4A shows measured sound curves 34-36 produced by several different internal sources. For example, a curve 34 may correspond to the sound level of blower noise from a HVAC blower when operating at a first speed. The HVAC blower has different operating speeds which each produce different sound curves 34-36. To increase the audibility of exterior sounds which may be present at the same frequencies occupied by blower noise, FIG. 4B shows a graph representing respective adjustments 37-39 (e.g. gain boosts) by frequency depending on the HVAC blower speed. The adjustment is selected which best masks the unwanted interior cabin sound.

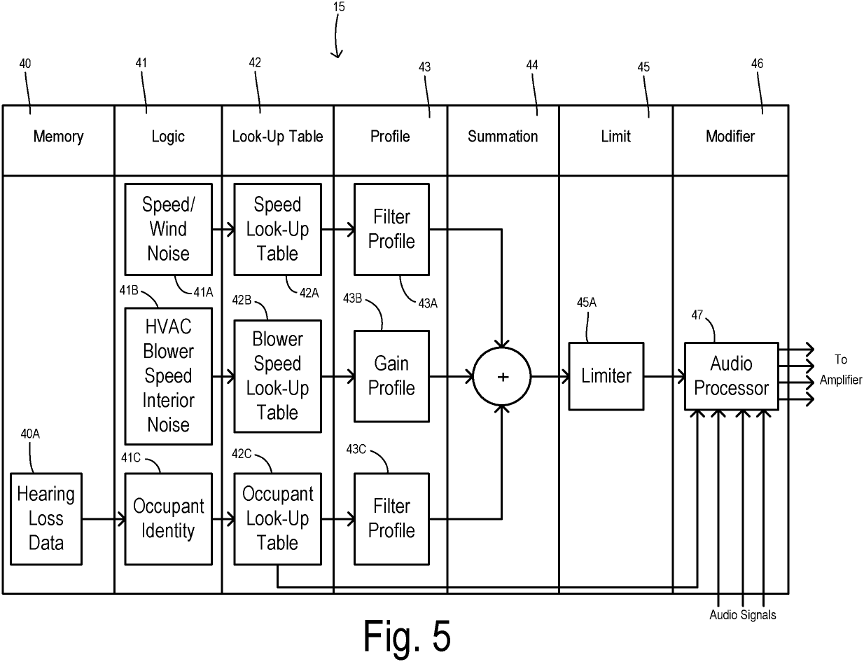

FIG. 5 shows one preferred embodiment of relevant portions of control circuit 15. Different forms of logic 41 are used to inform the control circuit. Logical elements include speed information 41A of the vehicle, an HVAC blower speed 41B, and occupant details 41C (e.g., the identity of the driver for whom a hearing loss curve has been stored or other parameters such as an actual hearing loss curve or an age of the driver for estimating hearing loss). Each logical element is used as an index to a corresponding look-up table 42 storing respective predetermined sound modifications to compensate for the different factors impacting the audibility of the exterior sounds. The indexed output of each look-up table is a profile 43 that modifies the audio signals. For instance, vehicle speed 41A is used as an index into look-up table 42A which outputs a unique filter profile 43A corresponding to the vehicle’s speed. This filter profile will mitigate the effects of wind noise by filtering the different frequencies of the exterior audio signals at different levels as mentioned above. Similarly, HVAC blower speed 41B used as an index into look-up table 42B which outputs a unique gain profile 43B corresponding to the blower speed. This gain profile will mitigate the effects of competing sounds in the interior of the vehicle by increasing different frequencies of the exterior audio signals at different levels as mentioned above. Finally, occupant details 41C are used as an index into look-up table 42C which outputs the data used for frequency shifting or compression (which is sent straight to the audio processor) as well as a unique gain profile 43C to compensate for hearing loss. Specific hearing deficiencies can be saved in memory 40 within the control circuit. The identity of the occupant corresponding with specific hearing deficiencies or exclusively age of the occupant, without any hearing loss data in memory, is used as an index into look-up table 42C which outputs a unique gain profile 43C corresponding to the occupant or occupants presently in the vehicle. These gain profiles will mitigate specific and general effects of hearing loss by increasing different frequencies of the exterior audio signals at different levels as mentioned above.

The gain and attenuation profiles may each be comprised of a function wherein a positive or negative gain is applied at each respective frequency within a range of audio frequencies. The separate gain profiles and attenuation profiles can be applied to the exterior audio signals from the microphone array either separately or together. When processed together, they can be combined in a summing block 44. Summing and applying all profiles to the audio signal might result in an audio signal that is too large (e.g., results in clipping). Therefore, a limiter 45A may be provided to restrict the adjustments made by the profiles 43 to a maximum predetermined gain. After being adjusted by limiter 45A, a combined profile is provided to an audio processor 47 in modifier 46 which applies the frequency-selective gains (e.g., increases and decreases in signal level) to a multi-channel audio signal based on the audio signals from the microphone array. Audio processor 47 may preferably be a digital audio processor which may convert the gain-modified audio signals to analog signals for distribution to internal transducers (e.g., main cabin speakers 20-23) via a multi-channel amplifier, thereby reproducing the apparent direction to sound sources outside the vehicle.

In a cabin with multiple occupants with both normal and poor hearing, reproduction of the compensated audio into the cabin could be objectionable to the occupant with normal hearing. In some embodiments, control circuit logic 41 may be configured to suspend adjustments when a normal hearing person is in the cabin or when the hard of hearing person is wearing their hearing aids, for example. Alternatively, the left/right and front/rear fader controls of the audio processor can be used to push the adjusted audio to the speaker(s) nearest the person hard of hearing.

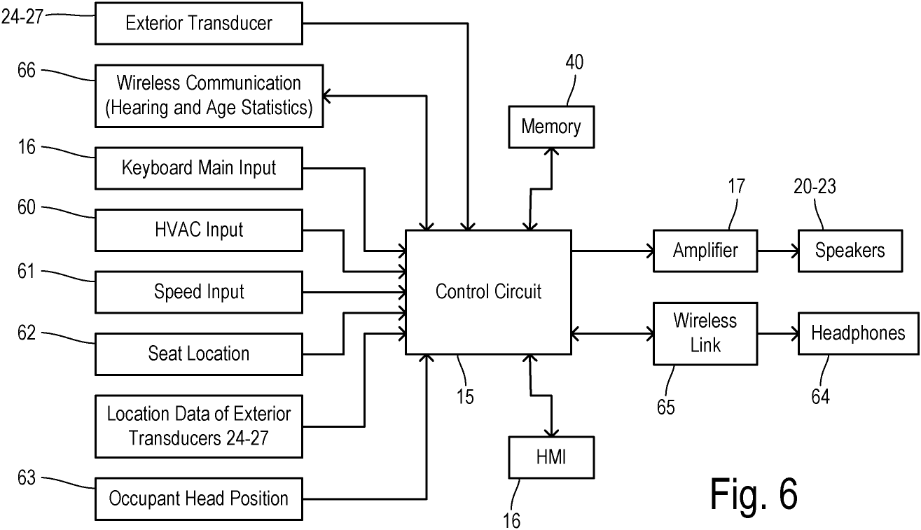

FIG. 6 depicts interactions of control circuit 15 with other vehicle components. The control circuit 15 can receive stored data signals from memory 40, microphone signals from exterior transducers 24-27, blower speed signals from an HVAC system 60, vehicle and/or engine speed signals from a powertrain controller 61, occupancy sensor signals from seat sensor 62 (e.g., seat location to estimate a listening position), and head position signals from a driver gaze detector 63. The control circuit is also connected to interior transducers 20-23 via amplifier 17, and/or to headphones or hearing aids 64 worn by an occupant via a wireless link 65 (e.g., a Bluetooth^{®} link). Control circuit 15 is also coupled to a wireless communication transceiver 66 (e.g., a cellular data connection) for contacting offboard data sources such as a remote server which stores data for hearing loss curves for specific individuals and/or for specific groups of people (e.g., based on age).

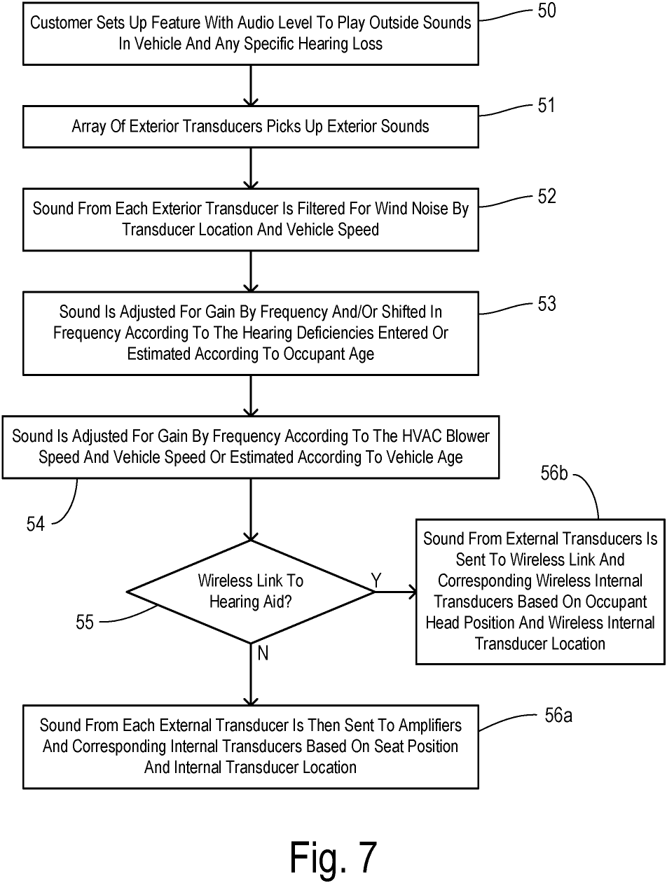

FIG. 7 shows a flowchart describing one preferred method. In step 50, an occupant uses an HMI to selectively activate the apparatus to reproduce exterior sounds. This may include adjusting the volume and saving their age and/or hearing loss data to the memory. In step 51, transducers on the exterior of the vehicle pick up the sounds on the exterior of the vehicle. In step 52, a filter profile is selected according to the vehicle speed and microphone location and then is used to attenuate each respective incoming microphone signal according to the exterior transducer location and vehicle speed. In step 53, a gain profile is selected according to an identification of the user (e.g., driver) and an assessment of their hearing loss, and the selected gain profile and/or frequency shifting or compression is used to adjust each channel of the audio signal according to the age and specific hearing deficiencies (entered in step 50) of an occupant. In step 54, a gain profile is selected according to an interior noise source competing with the desired exterior audio and the selected profile is used to make an adjustment for gain by frequency contingent on the interior noise level of the vehicle including an HVAC blower speed or an estimate of exterior noise that leaks into the vehicle cabin (which may be estimated in response to vehicle speed and vehicle age, for example). In step 55, a determination is made as to whether the vehicles interior cabin transducers or wireless headphone transducers will be used. In the former, step 56a will take place, and in the latter step 56b will take place. In step 56a, signals picked up by external transducers in step 51 and adjusted in steps 52-54 will be sent to amplifiers and corresponding internal loudspeakers which are fixed within the vehicle cabin. The control circuit may determine how to disperse the adjusted signal over the array of internal transducers depending on location of the external sounds and the seat position of the occupant. In step 56b, signals picked up by external transducers in step 51 and adjusted in steps 52-54 will be sent to corresponding wireless headphone speakers which may have an arbitrary left-right orientation with respect to the forward direction of the vehicle. The control circuit will determine how to disperse the adjusted signal over the wireless transducers depending on location of the external sounds, the seat position of the occupant, and the head position of the occupant.

Hearing deficiencies may be characterized by hearing loss data which are known by the occupant are entered into the vehicle and saved. The identity of the occupant is then selected which corresponds with a gain profile and/or frequency shifting or compression. If the occupant does not have saved hearing loss data, deficiencies can alternatively be estimated by age, wherein predetermined age ranges have their own corresponding gain profiles and/or frequency shifting or compression. These specific quantities of hearing loss data, specific gain profiles, and frequency shifting or compression are respectively similar to the graphs in FIGS. 3A and 3B.

There are exterior sounds that disturb the important and useful exterior sounds from being clearly received by the exterior transducers or microphones. A primary example is wind. The noise generated by the wind is dependent upon speed and microphone placement. Each speed/microphone may have a unique noise level profile. It may be possible for noise in certain frequencies to be entirely filtered out. This is dependent on whether these frequencies can represent useful sounds (e.g., spoken sounds, sirens, or other desirable sounds outside the vehicle). For instance, if the frequency contains only useless noises like wind, the frequency can be entirely filtered out from the signal transferred from the control circuit to the interior transducers. However, noises that are produced in a frequency containing both useless and useful noise, the frequency cannot be filtered out completely, but the sound level can be altered based upon their frequency prior to any modification based on hearing loss or competing interior noise sources.

There are interior sounds produced in, and or present in, the cabin that disturb the hearing of the reproduced exterior sounds. These sounds can include HVAC noise, vehicle body noise, and engine noises (which vary by speed) which enter the cabin (e.g., depending on factors such as door seal deterioration which depends on vehicle age). The HVAC operating in the cabin causes noise depending on the speed of the blower and the positions of airflow dampers. For each of these factors, the control circuit can be configured to apply a corresponding correction to the reproduced sound. Similar to a saved occupant identity or wind speed, each HVAC blower speed/damper positions, vehicle speed, and vehicle age may have a respective model or look-up table providing respective gain adjustments or profiles.

A sound field created by the interior transducers can also be adjusted based on the original sound field outside the vehicle so that the original directional relationships are preserved as heard at the occupant’s position. An originating exterior audio signal which is clearly originated in a distinct location will be transferred to the interior transducers that mirror the location of the originating exterior audio signal. The modified audio signal can be adjusted based on the occupant’s seat position, feeding the sound to the estimated location of the occupant’s head. If the interior transducers are headphones or wireless transducers, then the modified audio signal can be adjusted to compensate for any turning of the head away from the forward direction of the vehicle, for example. The adjustment will depend on the occupant’s direction of gaze so that the modified audio signal can constantly mirror the location of the originating exterior audio signal.

1. A vehicle apparatus comprising:
a vehicle structure with an interior and exterior,
an array of exterior sound transducers;
an array of interior sound transducers;
a control circuit configured to adjust an amplitude of signals received by the exterior transducer array according to a frequency selective gain curve to generate a modified audio signal including a frequency selective boost compensating for frequencies of hearing loss of an individual and an adjustment attenuating unwanted exterior noise based on vehicle speed and exterior transducer location; and
an amplifier which transfers signals from the control circuit to the array of interior transducers.

2. The vehicle apparatus of claim 1 wherein the control circuit is further configured to frequency shift at least a portion of the signals received by the exterior transducer array downward to further compensate for the hearing loss.

3. The vehicle apparatus of claim 1 wherein the control circuit provides additional gain by frequency according to noises present in the interior of the vehicle.

4. (canceled)

5. The vehicle apparatus of claim 1 wherein the unwanted exterior noise comprises wind noise, engine noise, or noise of tires on any surface.

6. The vehicle apparatus of claim 1 wherein the control circuit filters signals received by the exterior sound transducers.

7. The vehicle apparatus of claim 1 wherein a memory unit within the control circuit saves occupant data for characterizing hearing loss.

8. The vehicle apparatus of claim 7 wherein the occupant data is used to recognize an occupant and retrieve individual hearing impairment including specific frequencies in which impairment exists, triggering an individualized gain profile.

9. The vehicle apparatus of claim 8 wherein the individual hearing impairment further triggers a frequency shift of at least a portion of the signals received by the exterior transducer array downward.

10. The vehicle apparatus of claim 1 wherein the interior transducers disperse the modified signal to mimic exterior sound based on occupant seat position and the location of exterior sound picked up by the external sound transducers.

11. The vehicle apparatus of claim 1 wherein the interior sound transducers are comprised of wirelessly linked headphones used to generate the modified audio signal, and wherein the wireless linked headphones disperse the modified signal to mimic exterior sound based on occupant seat position, occupant head position, and the location of the exterior sound picked up by the external sound transducers.

12. The vehicle apparatus of claim 1 wherein a human machine interface (HMI) is configured to selectively enable the control circuit in response to an action by an occupant.

13. The vehicle apparatus of claim 1 wherein the array of exterior transducers is spaced around the exterior of the vehicle and the array of interior transducers are spaced around the interior of the vehicle.

14. A method of reproducing sounds exterior to a vehicle in an interior of a vehicle, comprising the steps of:
receiving sound at the exterior of a vehicle with an array of exterior sound transducers to generate an exterior audio signal;
filtering noise from the exterior audio signal using vehicle speed and location of the exterior sound transducers to generate a filtered audio signal;
adjusting an amplitude of the filtered audio signal according to a frequency selective gain curve based on hearing deficiencies of an occupant to generate a loss-compensated audio signal having a frequency selective boost;
adjusting an amplitude of the loss-compensated audio signal according to frequencies of competing sounds present in the interior of the vehicle to generate a modified audio signal; and
amplifying the modified audio signal for reproduction in the vehicle interior.

15. The method of claim 14 wherein adjusting the filtered audio signal to generate the loss-compensated audio signal further comprises frequency shifting at least a portion of the filtered audio signal received by the exterior transducer array downward.

16. The method of claim 14 wherein the adjustments for gain are compensation for the hearing deficiencies of an occupant and sound present in the interior of the vehicle.

17. The method of claim 14 wherein the adjustments for gain are compensation for estimated hearing deficiencies according to age of an occupant and estimated sound in the interior of the vehicle according to the age of the vehicle.

18. The method of claim 14 wherein the modified audio signal is subjected to a limiter for limiting a maximum gain by frequency.

19. A vehicle apparatus comprising:
a vehicle structure with an interior and exterior,
an array of exterior sound transducers;
an array of interior sound transducers;
a control circuit configured to adjust an amplitude of signals received by the exterior transducer array according to a frequency selective gain curve to generate a modified audio signal including a frequency selective boost compensating for frequencies of hearing loss of an individual and an adjustment for attenuating unwanted exterior noise based on vehicle speed and exterior transducer location; and
an amplifier which transfers signals from the control circuit to the array of interior transducers;
wherein the control circuit receives a logical input of an HVAC blower speed, the vehicle speed, and a vehicle age that relates to noise present in the interior of the vehicle, and wherein the control circuit provides a frequency-selective gain adjustment according to the logical input.
